(19) United States
(12) Patent Application Publication
(10) Pub. No.: US 2021/0083145 A1
(43) Pub. Date: Mar. 18, 2021

(54) LIGHT EMITTING DIODE DEVICE

(71) Applicant: Xiamen Sanan Optoelectronics Technology Co., Ltd, Fujian (CN)

(72) Inventors: Feng WANG, Fujian (CN); Gong CHEN, Fujian (CN); Hongwei XIA, Fujian (CN); Yu ZHAN, Fujian (CN); Ling-Yuan HONG, Fujian (CN); Su-Hui LIN, Fujian (CN); Kang-Wei PENG, Fujian (CN); Chia-Hung CHANG, Fujian (CN)

(73) Assignee: Xiamen Sanan Optoelectronics Technology Co., Ltd, Fujian (CN)

(21) Appl. No.: 17/105,294

(22) Filed: Nov. 25, 2020

Related U.S. Application Data
(63) Continuation-in-part of application No. PCT/CN2019/072025, filed on Jan. 16, 2019.

(30) Foreign Application Priority Data
Jun. 28, 2018 (CN) 201821012260.0

(51) Int. Cl. H01L 33/22; H01L 33/14

(52) U.S. Cl. CPC H01L 33/22; H01L 33/14

(57) ABSTRACT

A light emitting diode device includes a light emitting epitaxial layered structure and a current spreading layer formed on the light emitting epitaxial layered structure. The current spreading layer has a top surface and a bottom surface that are respectively distal from and proximal to the light emitting epitaxial layered structure, and a peripheral surface that interconnects the top surface and the bottom surface and that is formed with a first patterned structure. The peripheral surface and the bottom surface cooperatively define an interior angle included therebetween which is greater than 90° and smaller than 180°.

### CROSS-REFERENCE TO RELATED APPLICATION

This application is a continuation-in-part (CIP) of International Application No. PCT/CN2019/072025, filed on Jan. 16, 2019, which claims priority of Chinese Utility Model Patent Application No. 201821012260.0, filed on Jun. 28, 2018. The entire content of each of the international and Chinese patent applications is incorporated herein by reference.

### FIELD

The disclosure relates to a light emitting diode device, and more particularly to a light emitting diode device having patterned structures on a peripheral face thereof.

### BACKGROUND

Group III-V compounds are the main semiconductor materials used for manufacturing light emitting diode (LED) devices, and among such compounds, gallium nitride (GaN) and aluminum gallium indium phosphide (AlGaInP) are the most common ones.

A conventional GaN-based LED device is made by the following techniques: mesa etching (forming an n-type platform), and formation of a current block (CB) layer, a transparent conductive layer (TCL, serving as a current spreading layer), pads and a passivation layer (PV). During formation of the TCL, to ensure that the wet etching of the current spreading layer (such as an indium tin oxide (ITO) layer) is conducted precisely to avoid current leakage, the ITO layer would be unavoidably overetched. Because wet etching is an isotropic etching, the edge of the ITO layer, even if pre-formed with a pattern, would still show a plain structure after wet etching (see FIG. 1). Furthermore, in the isotropic etching, an upper portion of the ITO layer proximal to a photoresist would be etched more compared to that of a bottom portion of the ITO layer distal from the photoresist, resulting in the ITO layer having an inclined peripheral surface that cooperates with a bottom surface to define an acute angle (see FIG. 2). Such plain structure and acute angle of the ITO layer would increase total internal reflection, and thus reduces light extraction from lateral surfaces of the LED device.

### SUMMARY

Therefore, an object of the disclosure is to provide an LED device that can alleviate at least one of the drawbacks of the prior art.

According to the disclosure, the LED device includes a light emitting epitaxial layered structure and a current spreading layer formed on the light emitting epitaxial layered structure. The current spreading layer has a top surface and a bottom surface that are respectively distal from and proximal to the light emitting epitaxial layered structure, and a peripheral surface that interconnects the top surface and the bottom surface and that is formed with a first patterned structure. The peripheral surface and the bottom surface cooperatively define an interior angle included therebetween which is greater than 90° and smaller than 180°.

### BRIEF DESCRIPTION OF THE DRAWINGS

Other features and advantages of the disclosure will become apparent in the following detailed description of the embodiment with reference to the accompanying drawings, of which:

FIG. 1 is a partial top view of an optical microscope (OM) image of a conventional GaN-based LED device;

FIG. 2 is a partial cross-sectional view of a scanning electron microscope (SEM) image of the conventional GaN-based LED device;

FIG. 3 is a schematic top view illustrating a first embodiment of an LED device according to the disclosure;

FIG. 4 is a schematic cross-sectional view illustrating the first embodiment;

FIG. 5 is a partial top view of an OM image illustrating a current spreading layer in the first embodiment;

FIG. 6 is a partial cross-sectional view of a SEM image illustrating an interior angle (θ) included between a peripheral surface and a bottom surface of the current spreading layer in the first embodiment of the LED device;

FIGS. 7A and 7B are schematic top and side views illustrating optical paths in a current spreading layer of the conventional LED device;

FIGS. 7C and 7D are schematic top and side views illustrating optical paths in the current spreading layer of the first embodiment;

FIG. 8 is a schematic cross-sectional view illustrating a second embodiment of the LED device according to the disclosure;

FIG. 9 is a schematic top view illustrating a third embodiment of the LED device according to the disclosure; and

FIG. 10 is a schematic cross-sectional view illustrating a fourth embodiment of the LED device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

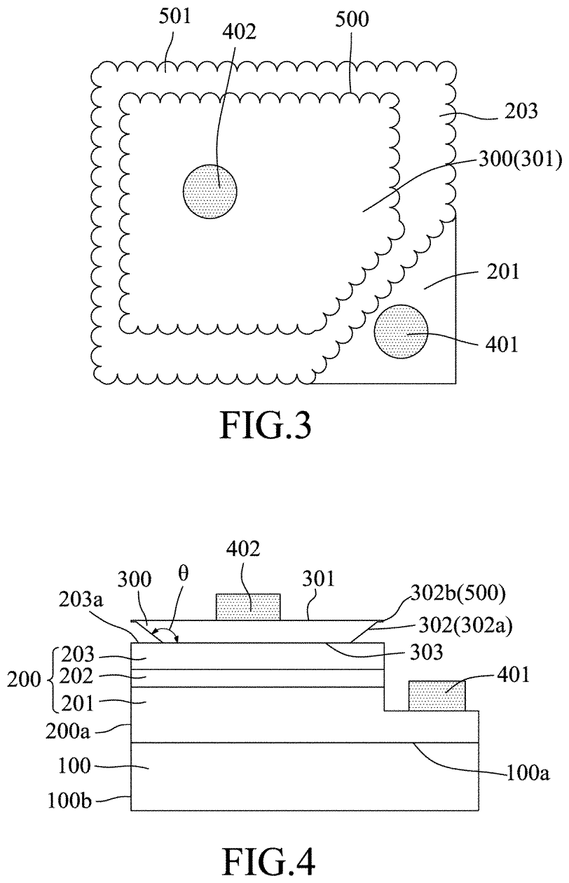

Referring to FIGS. 3 to 6, a first embodiment of an LED device according to the disclosure, such as a GaN-based LED device, includes a substrate 100, a light emitting epitaxial layered structure 200, a current spreading layer 300 formed on the light emitting epitaxial layered structure 200, an N-type electrode 401, and a P-type electrode 402.

The substrate 100 may be made of a material selected from sapphire, aluminum nitride, silicon, and silicon carbide. In this embodiment, the substrate 100 is made of sapphire. The substrate 100 has a substrate surface 100a that is connected to the light emitting epitaxial layered structure 200 opposite to the current spreading layer 300, and a side surface 100b that extends peripherally from the substrate surface 100a. The substrate surface 100a may be a plain surface or a roughed surface.

The light emitting epitaxial layered structure 200 includes a first-type semiconductor layer 201 disposed on the substrate surface 100a of the substrate 100, a second-type semiconductor layer 203 spaced apart from the first-type semiconductor layer 201, and a light emitting layer 202 that is sandwiched between the first-type semiconductor layer 201 and the second-type semiconductor layer 203.

The light emitting epitaxial layered structure 200 is made of a material selected from the group consisting of a GaN-based material, a gallium phosphide-based material, a gallium nitride phosphide-based material, and a zinc oxide-based material. In this embodiment, the light emitting epitaxial layered structure 200 is made of a GaN-based material. For example, the first-type semiconductor layer 201 is an N-type semiconductor layer made of N-GaN and the second-type semiconductor layer 203 is a P-type semiconductor layer made of P-GaN. The light emitting layer 202 is an active layer including a multi-quantum well (MQW) structure made of a material selected from the group consisting of AlGaN, InAlGaN, GaN and InGaN.

The current spreading layer 300 may be made of a material selected from the group consisting of indium tin oxide (ITO), zinc oxide (ZnO), cadmium tin oxide (CTO), indium oxide (InO), zinc oxide (ZnO) doped with indium (In), zinc oxide (ZnO) doped with aluminum (Al), and zinc oxide (ZnO) doped with gallium (Ga). In this embodiment, the current spreading layer 300 is made of ITO.

The current spreading layer 300 has a top surface 301 and a bottom surface 303 that are respectively distal from and proximal to the light emitting epitaxial layered structure 200, and a peripheral surface 302 that interconnects the top surface 301 and the bottom surface 303. The peripheral surface 302 and the bottom surface 303 cooperatively define an interior angle θ included therebetween which is greater than 90° and smaller than 180°. The peripheral surface 302 is formed with a first patterned structure 500.

The N-type electrode 401 is formed on an exposed portion of the first-type semiconductor layer 201 that is not covered by the light emitting layer 202 and the second-type semiconductor layer 203. The P-type electrode 402 is formed on the top surface 301 of the current spreading layer 300.

In certain embodiments, the interior angle θ included between the peripheral surface 302 and the bottom surface 303 of the current spreading layer 300 ranges from 120° to 150°, such as 135°.

The peripheral surface 302 of the current spreading layer 300 has an inclined region 302a that is connected to the bottom surface 303 and an upper edge region 302b that is connected to the top surface 301 and the inclined region 302a. The first patterned structure 500 may be formed on one of the inclined region 302a, the upper edge region 302b, and a combination thereof. The first patterned structure 500 may have one of a wave pattern, a triangular pattern, and a step pattern.

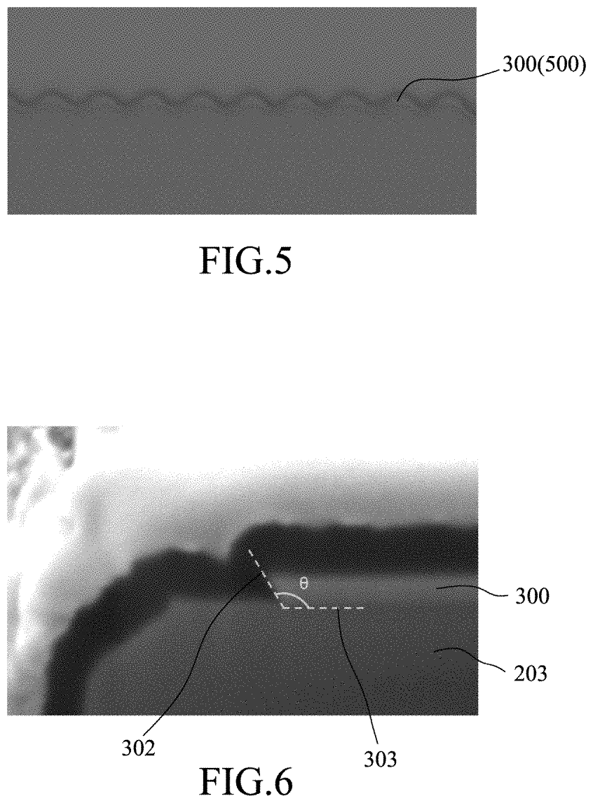

In this embodiment, the first patterned structure 500 has a wave pattern (see FIG. 5) and is formed on the upper edge region 302b, and the inclined region 302a has a planar structure (see FIGS. 4 and 6), which may be made as follows.

First, a silicon oxide layer is disposed on the current spreading layer 300 opposite to the light emitting epitaxial layered structure 200, and then a photoresist layer having a wave pattern on a periphery thereof partially covers the silicon oxide layer to expose a portion of the silicon oxide layer. Then, the silicon oxide layer, the current spreading layer 300 and the light emitting epitaxial layered structure 200 are subjected to a dry etching process (such as inductively coupled plasma (ICP) etching), so as to remove the exposed portion of the silicon oxide layer, as well as portions of the current spreading layer 300, the second-type semiconductor layer 203, the light emitting layer 202 and the first-type semiconductor layer 201 that are disposed below the silicon oxide layer, and to obtain the wave pattern on the upper edge region 302b of the current spreading layer 300. Then, the peripheral surface 302 of the current spreading layer 300 is subjected to a selective wet etching process using an etching solution. Since an upper portion of the current spreading layer 300 proximal to the silicon oxide layer may be etched by the etching solution at an etching rate lower than the etching rate of a bottom portion of the current spreading layer 300 distal from the silicon oxide layer, the inclined region 302a of the current spreading layer 300 is thus formed, and cooperates with the bottom surface 303 to define an obtuse angle. After the wet etching process performed on the current spreading layer 300, the silicon oxide layer and the photoresist are removed.

In certain embodiments, the light emitting epitaxial layered structure 200 has a lateral surface 200a that is formed with a second patterned structure 501, which may be formed by, for example, disposing a template having a ball pattern (such as arrays of polystyrene (PS) balls or SiO₂ balls) on the lateral surface 200a and then conducting an anisotropic wet etching process thereon. The lateral surface 200a of the light emitting epitaxial layered structure 200 is defined by at least one selected from the group consisting of a lateral face of the first-type semiconductor layer 201, a lateral face of the second-type semiconductor layer 203, and a lateral face of the light emitting layer 202. That is to say, the lateral face of the first-type semiconductor layer 201, the lateral face of the second-type semiconductor layer 203 and/or the lateral face of the light emitting layer 202 may be formed with the second patterned structure 501. In this embodiment, the lateral face of the second-type semiconductor layer 203 is formed with the second patterned structure 501. The second patterned structure 501 may have one of a wave pattern, a triangular pattern, and a step pattern. In this embodiment, the first patterned structure 500 and the second patterned structure 501 has a same pattern, i.e., a wave pattern.

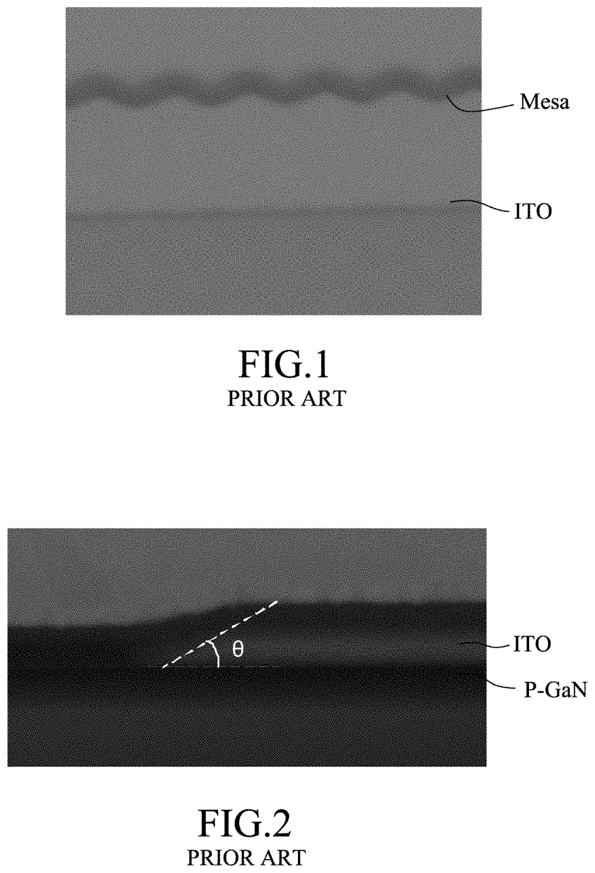

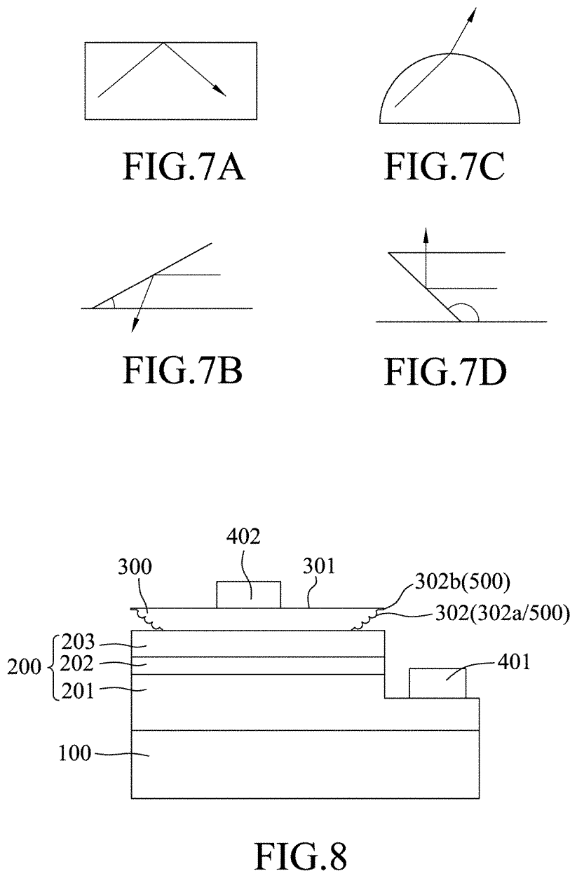

Referring to FIGS. 7A and 7B, since the conventional LED device as shown in FIGS. 1 and 2 includes the current spreading layer having the planar structure as observed from a top view, and an acute angle defined between the peripheral surface and the bottom surface thereof as observed from a side view, the light entering the current spreading layer would undergo total internal reflection, and the light extraction efficiency from lateral surfaces of the conventional LED device would be significantly reduced. In contrast, as shown in FIGS. 7C and 7D, the current spreading layer 300 of the first embodiment of the LED device, which has a patterned structure (wave pattern) as observed from a top view and an obtuse angle defined between the peripheral surface and the bottom surface as observed from a side view, can prevent the total internal reflection of the light, so as to improve the light extraction efficiency of the LED device according to this disclosure.

Referring to FIG. 8, a second embodiment of the LED device is generally similar to the first embodiment, except that in the second embodiment, the first patterned structure 500 is formed on both of the inclined region 302a and the upper edge region 302b. The first patterned structure 500 formed on the inclined region 302a may be made by, for example, disposing a template having a ball pattern (such as arrays of PS or SiO₂ balls) on the peripheral surface 302, followed by conducting an anisotropic wet etching process on the peripheral surface 302.

In this way, a total area of the first patterned structure 500 on the peripheral surface 302 may be increased so that more light can be extracted from the peripheral surface 302 of the current spreading layer 300.

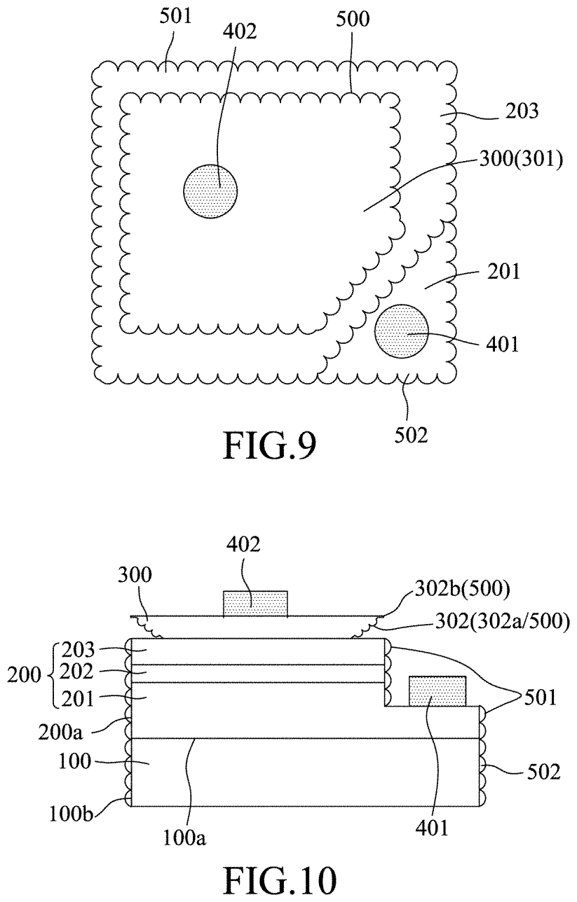

Referring to FIG. 9, a third embodiment of the LED device is generally similar to the second embodiment, except that in the third embodiment, the second patterned structure 501 is formed on the lateral face of the first-type semiconductor layer 201, the lateral face of the light emitting layer 202, and the lateral face of the second-type semiconductor layer 203. In this way, a total area of the second patterned structure 501 on the lateral surface 200a may be increased so that more light can be extracted from the lateral surface 200a of the light emitting epitaxial layered structure 200.

Referring to FIG. 10, a fourth embodiment of the LED device is generally similar to the third embodiment, except that in the fourth embodiment, the side surface 100b of the substrate 100 in the fourth embodiment is formed with a third patterned structure 502, which may be formed by, for example, disposing a template having a ball pattern (such as arrays of PS or SiO₂ balls) on the side surface 100b and then conducting an anisotropic wet etching process thereon. The third patterned structure 502 has one of a wave pattern, a triangular pattern, and a step pattern. In this embodiment, the first patterned structure 500 and the third patterned structure 502 have a same pattern. In this way, a total patterned area on a peripheral face of the LED device may be increased so that more light can be extracted therefrom.

In conclusion, the LED device of this disclosure has the following advantages.

First, by controlling the interior angle θ defined between the peripheral surface 302 and the bottom surface 303 of the current spreading layer 300 to be greater than 90° and smaller than 180°, an light-exit angle may be varied and an area of the peripheral surface for light exiting therefrom is increased. Therefore, the light emitted from the light emitting layer 202 may easily exit from the LED device (rather than being confined within the LED device which causes an optical loss), so as to increase a light extraction efficiency of the LED device.

Second, by forming the first patterned structure 500 on the peripheral surface 302 of the current spreading layer 300, or further forming the second and the third patterned structures 501, 502 respectively on the lateral surface 200a of the light emitting epitaxial layered structure 200 and the side surface 100b of the substrate 100, the total internal reflection of light within the LED device may be reduced or even eliminated, and thus more light may exit from the peripheral face of the LED device in an efficient manner, thereby improving the light extraction efficiency of the LED device.

In the description above, for the purposes of explanation, numerous specific details have been set forth in order to provide a thorough understanding of the embodiments. It will be apparent, however, to one skilled in the art, that one or more other embodiment may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A light emitting diode device, comprising:
a light emitting epitaxial layered structure; and
a current spreading layer formed on said light emitting epitaxial layered structure, and having a top surface and a bottom surface that are respectively distal from and proximal to said light emitting epitaxial layered structure, and a peripheral surface that interconnects said top surface and said bottom surface,
wherein said peripheral surface and said bottom surface cooperatively define an interior angle included therebetween which is greater than 90° and smaller than 180°.

2. The light emitting diode device of claim 1, wherein the interior angle ranges from 120° to 150°.

3. The light emitting diode device of claim 1, wherein said peripheral surface is formed with a first patterned structure.

4. The light emitting diode device of claim 3, wherein said peripheral surface has an inclined region that is connected to said bottom surface and an upper edge region that is connected to said top surface and said inclined region, said first patterned structure being formed on one of said inclined region, said upper edge region, and a combination thereof.

5. The light emitting diode device of claim 4, wherein said light emitting epitaxial layered structure has a lateral surface which is formed with a second patterned structure.

6. The light emitting diode device of claim 5, wherein said light emitting epitaxial layered structure includes a first-type semiconductor layer, a second-type semiconductor layer, and a light emitting layer that is sandwiched between said first-type semiconductor layer and said second-type semiconductor layer, said lateral surface of said light emitting epitaxial layered structure being defined by at least one selected from the group consisting of a lateral face of said first-type semiconductor layer, a lateral face of said second-type semiconductor layer, and a lateral face of said light emitting layer.

7. The light emitting diode device of claim 5, wherein each of said first patterned structure and said second patterned structure has one of a wave pattern, a triangular pattern and a step pattern.

8. The light emitting diode device of claim 5, wherein said first patterned structure and said second patterned structure have a same pattern.

9. The light emitting diode device of claim 3, further comprising a substrate having a substrate surface connecting to said light emitting epitaxial layered structure opposite to said current spreading layer.

10. The light emitting diode device of claim 9, wherein said substrate has a side surface which extends peripherally from said substrate surface and which is formed with a third patterned structure.

11. The light emitting diode device of claim 10, wherein each of said first patterned structure and said third patterned structure has one of a wave pattern, a triangular pattern, and a step pattern.

12. The light emitting diode device of claim 10, wherein said first patterned structure and said third patterned structure have a same pattern.

13. The light emitting diode device of claim 10, wherein said light emitting epitaxial layered structure has a lateral surface which is formed with a second patterned structure.

14. The light emitting diode device of claim 13, wherein each of said first patterned structure, said second patterned structure and said third patterned structure has one of a wave pattern, a triangular pattern, and a step pattern.

15. A light emitting diode device, comprising:
a light emitting epitaxial layered structure; and
a current spreading layer formed on said light emitting epitaxial layered structure, and having a top surface and a bottom surface that are respectively distal from and proximal to said light emitting epitaxial layered structure, and a peripheral surface that interconnects said top surface and said bottom surface and that is formed with a first patterned structure.

16. The light emitting diode device of claim 15, wherein said first patterned structure has one of a wave pattern, a triangular pattern and a step pattern.

17. The light emitting diode device of claim 15, wherein said light emitting epitaxial layered structure has a lateral surface which is formed with a second patterned structure.

18. The light emitting diode device of claim 17, wherein said first patterned structure and said second patterned structure have a same pattern.

19. The light emitting diode device of claim 15, further comprising a substrate having a substrate surface connecting to said light emitting epitaxial layered structure opposite to said current spreading layer and a side surface which extends peripherally from said substrate surface and which is formed with a third patterned structure.

20. The light emitting diode device of claim 19, wherein each of said first patterned structure and said third patterned structure has one of a wave pattern, a triangular pattern, and a step pattern.
